(19) United States
(12) Patent Application Publication
(10) Pub. No.: US 2026/0297317 A1
(43) Pub. Date: Oct. 1, 2026

(54) RESIN COMPOSITION, PREPREG, RESIN FILM, METAL-CLAD LAMINATED PLATE, PRINTED WIRING BOARD, AND SEMICONDUCTOR PACKAGE

(71) Applicant: Resonac Corporation, Tokyo (JP)

(72) Inventors: Yusuke SERA, Tokyo (JP); Shinichiro ABE, Tokyo (JP); Ai YOKOKURA, Tokyo (JP); Yuji MATO, Tokyo (JP); Nene HATAKEYAMA, Tokyo (JP)

(21) Appl. No.: 19/480,720

(22) PCT Filed: Oct. 22, 2024
(86) PCT No.: PCT/JP2024/037488

§ 371 Date: Oct. 31, 2025

(30) Foreign Application Priority Data
Oct. 23, 2023 (JP) 2023-181836

(51) Int. Cl. C08L 25/16; C08J 5/24; H10W 70/695

(52) U.S. Cl. CPC C08L 25/16; C08J 5/244; H10W 70/695; C08J 2325/16; C08J 2353/02

(57) ABSTRACT

A resin composition comprising a polyfunctional vinylbenzyl compound (A) having two or more vinylbenzyl groups, and a styrene copolymer (B) having a weight average molecular weight of 20,000 or less and having a vinyl group. A prepreg, a resin film, a metal clad laminate, a printed wiring board, and a semiconductor package formed using this resin composition.

### TECHNICAL FIELD

The present disclosure relates to a resin composition, a prepreg, a resin film, a metal clad laminate, a printed wiring board, and a semiconductor package.

### BACKGROUND ART

Metal clad laminates represented by copper clad laminates, prepregs that can be used for metal clad laminates, and semiconductor packages including metal clad laminates are used in various electronic devices such as portable communication devices such as smartphones, personal computers, industrial computers, servers, large servers, routers, and mobile base stations. In addition, they are also used in electronic devices mounted in home electric appliances, automobiles, and the like. Among them, a demand for electronic communication devices that process massive amounts of data at high speeds is increasing due to the spread of 5G.

In the electronic device, when massive amounts of data are processed at high speeds, a substrate material having a low transmission loss in a high-frequency range is required. A resin having low permittivity and low dissipation factor is used for the substrate material to provide a substrate having low dielectric loss, but with the recent developments in the communication technology, the development of resins having lower permittivity and lower dissipation factor is being required.

Patent Literature 1 discloses a thermosetting resin composition that includes a vinylbenzyl-based compound and a polycarbodiimide compound as materials for electronic components used in a high-frequency band, proposing that the obtained electronic components improve adhesion to a metal material while excellent dielectric properties are maintained.

### CITATION LIST

### Patent Literature

Patent Literature 1: Japanese Patent Laid-Open No. 2007-119531

### SUMMARY OF INVENTION

### Technical Problem

In Patent Literature 1, a vinylbenzyl-based compound excellent in dielectric properties in a high-frequency band is proposed, and, as specific examples, low permittivity and low dissipation factor are achieved in a cured product of a resin composition containing a vinylbenzyl-based compound alone. However, a material design that exhibits more excellent dielectric properties is desired.

In addition, a metal clad laminate can be obtained by forming a metal foil on a surface of a laminate of a prepreg in which a resin is impregnated into a fiber substrate, and curing the prepreg by application of pressure and heat. Due to its structure, the metal clad laminate exhibits rigidity and is also a substrate material having excellent warpage characteristics and flatness. Furthermore, in order to reduce transmission loss, it is also required to enhance the impregnation and coating properties of the resin composition into the fiber substrate and to more strictly control transmission loss caused by coating defects and the like. There are also similar problems in resin films.

An object of the present disclosure is to provide a resin composition for providing a product having high reliability and excellent dielectric properties, and a prepreg, a resin film, a metal clad laminate, a printed wiring board, and a semiconductor package having high reliability and excellent dielectric properties.

### Solution to Problem

The present disclosure includes the following embodiments. The present disclosure is not limited to the following embodiments.

One embodiment relates to a resin composition comprising a polyfunctional vinylbenzyl compound (A) having two or more vinylbenzyl groups, and a styrene copolymer (B) having a weight average molecular weight of 20,000 or less and having a vinyl group.

### Advantageous Effects of Invention

According to the present disclosure, it is possible to provide a resin composition for providing a product having high reliability and excellent dielectric properties, and a prepreg, a resin film, a metal clad laminate, a printed wiring board, and a semiconductor package having high reliability and excellent dielectric properties.

### BRIEF DESCRIPTION OF DRAWING

FIG. 1 is a pattern diagram used in Examples.

### DESCRIPTION OF EMBODIMENTS

Hereinafter, the embodiments of the present invention will be described in detail. The present invention is not limited to the following embodiments.

In the present disclosure, a numerical value range indicated by using “to” indicates a range that includes the numerical values described before and after “to” as the minimum value and the maximum value, respectively. In the numerical value ranges described stepwise in the present disclosure, the upper limit value or the lower limit value of a certain numerical value range may be replaced with the upper limit value or the lower limit value of another numerical value range. Furthermore, the upper limit value or the lower limit value of the numerical value range described in the present disclosure may be replaced with values shown in Examples. In the present disclosure, unless otherwise specified, each component may contain one kind or two or more kinds of the corresponding substances. In the present disclosure, unless otherwise specified, when there are a plurality of substances corresponding to each component in the resin composition, a content of each component in the resin composition means a total amount of the plurality of substances present in the resin composition.

In the present disclosure, a weight average molecular weight (Mw) and a number average molecular weight (Mn) of a polymer are measured values according to the following measurement methods, unless otherwise specified.

A weight average molecular weight and a number average molecular weight of a polymer are converted from a calibration curve using standard polystyrene by gel permeation chromatography (GPC). The calibration curve is approximated by a cubic equation using standard polystyrene: TSKstandard POLYSTYRENE (Type; A-2500, A-5000, F-20, F-80) (available from Tosoh Corporation, product name). The measurement conditions of GPC are shown below.
Device: High-speed GPC device “HLC-8320GPC” (Tosoh Corporation, product name)
Detector: Ultraviolet absorbance detector “UV-8320” (Tosoh Corporation, product name)
Column: Guard column; TSKgel guardcolumn Super (HZ)-M+, Column; TSKgel SuperMultipore HZ-M (2 columns), Reference column; TSKgel SuperH-RC (2 columns) (all from Tosoh Corporation, product names)
Column size: 4.6×20 mm (guard column), 4.6×150 mm (column), 6.0×150 mm (reference column)
Eluent: Tetrahydrofuran
Sample concentration: 10 mg/1 mL
Injection amount: 20 μL or 2 μL
Flow rate: 0.35 mL/min
Measurement temperature: 40° C.

### “Resin Composition”

A resin composition according to one embodiment includes a polyfunctional vinylbenzyl compound (A) having two or more vinylbenzyl groups, and a styrene copolymer (B) having a weight average molecular weight of 20,000 or less and having a vinyl group.

In the present disclosure, the “polyfunctional vinylbenzyl compound (A) having two or more vinylbenzyl groups” is also referred to as “polyfunctional vinylbenzyl compound (A)”. In addition, the “styrene copolymer (B) having a weight average molecular weight of 20,000 or less and having a vinyl group” is also referred to as “styrene copolymer (B)”.

Use of this resin composition makes it possible to provide a product having high reliability and excellent dielectric properties. Without wishing to be bound by any theory, the reason for this is because use of this resin composition makes it possible to alleviate stress in a coating film of the resin composition and to suppress occurrence of fine cracks in the coating film in the coating film state. A cured product of such a resin composition is excellent in electrochemical migration resistance because fine defects are precisely controlled. A product containing the cured product of such a resin composition has high reliability.

When this resin composition includes a polyfunctional vinylbenzyl compound (A) as a curable compound and a styrene copolymer (B) as an elastomer, it is possible to achieve lower permittivity and lower dissipation factor in the cured product of the resin composition compared to a case where the polyfunctional vinylbenzyl compound (A) is used alone. Moreover, the styrene copolymer (B) can improve the reliability of the resulting product as described above when used in combination with the polyfunctional vinylbenzyl compound (A). One reason for this is because the styrene copolymer (B) has a weight average molecular weight of 20,000 or less, and therefore sufficient flexibility is imparted to the coating film of the resin composition, which is believed to suppress the occurrence of fine cracks in the coating film state.

The polyfunctional vinylbenzyl compound (A) is a polyfunctional compound having two or more vinylbenzyl groups. The polyfunctional vinylbenzyl compound (A) is one that can obtain a cured product by promoting the reaction of the vinylbenzyl groups within or between molecules using heating, pressure, a curing agent, and the like, because it has two or more vinylbenzyl groups in the molecule.

The polyfunctional vinylbenzyl compound (A) may be a monomer, an oligomer, or a prepolymer, and a combination of two or more kinds thereof may be included in the resin composition.

When the polyfunctional vinylbenzyl compound (A) is a monomer, it may be one in which two or more vinylbenzyl groups are introduced into a base compound. An oligomer may be a compound having a low degree of polymerization in which two or more monomers described above are polymerized. A prepolymer may be one in which two or more vinylbenzyl groups are introduced into a resin skeleton, and may be a polymer of a monomer, an oligomer, or a combination thereof having two or more vinylbenzyl groups. The prepolymer contains a certain amount of unreacted vinylbenzyl groups and is preferably a state in which the curing reaction is initiated by heating or the like.

In the monomer in the polyfunctional vinylbenzyl compound (A), the number of vinylbenzyl groups may be 2 to 4 or 2 to 3.

In the oligomer or the prepolymer of the polyfunctional vinylbenzyl compound (A), the number of vinylbenzyl groups in a molecule may be 2 or more, but a monomer structural unit preferably includes 2 or more vinylbenzyl groups, and the monomer structural unit may have 2 to 4 vinylbenzyl groups or 2 to 3 vinylbenzyl groups.

In the polyfunctional vinylbenzyl compound (A), the vinylbenzyl group may be an o-vinylbenzyl group, an m-vinylbenzyl group, or a p-vinylbenzyl group. In one molecule of the polyfunctional vinylbenzyl compound (A), two or more vinylbenzyl groups may be isomers that are identical to or different from each other. From the perspective of dielectric properties, at least one vinylbenzyl group in one molecule of the polyfunctional vinylbenzyl compound (A) is preferably a p-vinylbenzyl group.

When the polyfunctional vinylbenzyl compound (A) includes a p-vinylbenzyl group, dielectric properties are further improved, and, in particular, a cured product exhibiting lower dissipation factor can be provided. From this perspective, in one molecule of the polyfunctional vinylbenzyl compound (A), the p-vinylbenzyl group relative to the total mass of all vinylbenzyl groups may be 10 to 100 mass %, 20 to 80 mass %, 30 to 70 mass %, or 40 to 60 mass %.

In the polyfunctional vinylbenzyl compound (A), the vinylbenzyl group may be unsubstituted or may have a substituent. When it has a substituent, the substituent may be, for example, an aliphatic hydrocarbon group having 1 to 20, 1 to 8, or 1 to 4 carbon atoms, and may be an alkyl group having the number of carbon atoms described above. In addition, it may have a halogen atom as a substituent, and may have, for example, a fluorine atom, a chlorine atom, a bromine atom, or an iodine atom. In the vinylbenzyl group, at least one of 1 to 4 hydrogen atoms bonded to the benzene ring may be substituted, and when it has two or more substituents, the substituents may be identical to or different from each other. In the polyfunctional vinylbenzyl compound (A), the presence or absence, the number, and the kind of substituents between two or more vinylbenzyl groups may be identical to or different from each other. The polyfunctional vinylbenzyl compound (A) preferably includes at least one unsubstituted vinylbenzyl group from the perspective of dielectric properties, and all vinylbenzyl groups may be unsubstituted.

The polyfunctional vinylbenzyl compound (A) is preferably a hydrocarbon compound, and a structure other than the vinylbenzyl group may be a non-aromatic hydrocarbon structure such as a chain-type hydrocarbon structure and an alicyclic hydrocarbon structure, or an aromatic hydrocarbon structure, but is preferably an aromatic hydrocarbon structure from the perspective of thermal properties. The aromatic hydrocarbon structure may be a monocyclic or polycyclic aromatic ring, a condensed ring of two or more aromatic rings, a condensed ring of an aromatic ring and a non-aromatic ring, or the like.

Examples of the aromatic hydrocarbon structure include an indene ring, an indane ring, a phenanthrene ring, an acenaphthylene ring, and a fluorene ring. From the perspective of dielectric properties, an indene ring and a fluorene ring are preferable. More preferably, the polyfunctional vinylbenzyl compound (A) is a compound having an indene ring. In addition, the vinylbenzyl group is preferably directly bonded to a carbon atom on the ring of the aromatic hydrocarbon structure.

When the polyfunctional vinylbenzyl compound (A) contains an aromatic hydrocarbon structure, an indene ring, an indane ring, a phenanthrene ring, an acenaphthylene ring, a fluorene ring, and the like may be unsubstituted or may have a substituent. Note that, a bonding site with the vinylbenzyl group is excluded. Examples of the substitute include, for example, those described in the above-described vinylbenzyl group. For example, when the polyfunctional vinylbenzyl compound (A) contains an indene ring, at least one of a plurality of hydrogen atoms bonded to the indene ring may be substituted. When it contains two or more substituents, they may be identical to or different from each other. When the polyfunctional vinylbenzyl compound (A) contains an aromatic hydrocarbon structure, from the perspective of dielectric properties, an indene ring, an indane ring, a phenanthrene ring, an acenaphthylene ring, a fluorene ring, and the like may be unsubstituted except for the bonding site with the vinylbenzyl group.

Hereinafter, a monomer of the polyfunctional vinylbenzyl compound (A) will be described. The polyfunctional vinylbenzyl compound (A) as a monomer is preferably a hydrocarbon compound. Among hydrocarbon compounds, a compound having an indene ring, an indane ring, a phenanthrene ring, an acenaphthylene ring, a fluorene ring, or the like, or a combination thereof is preferable, a compound having an indene ring, a fluorene ring, or a combination thereof is more preferable, and a compound having an indene ring is still more preferable. For example, the polyfunctional vinylbenzyl compound (A) may be a monomer that has two or more vinylbenzyl groups and one indene ring in one molecule.

One example of the polyfunctional vinylbenzyl compound (A) is a monomer that has an indene ring and has two or more vinylbenzyl groups bonded to the 1-position, the 2-position, or the 3-position of the indene ring.

Specific examples of the polyfunctional vinylbenzyl compound (A) include a monomer represented by the following Formula (1).

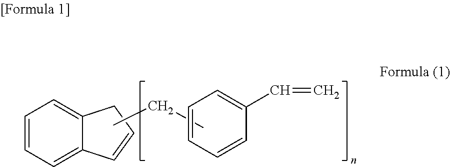

In the Formula (1), n is 2 or 3. Note that, in a mixture of the monomers represented by the Formula (1), it may include a plurality of kinds of monomers having different ns. In this case, n is preferably 2 to 3, and more preferably 2.0 to 2.5 on average. Furthermore, the resin composition may also contain a vinylbenzyl compound where n is 1 in the Formula (1). In this case, in a mixture of the vinylbenzyl compounds where n is 1 to 3 in the Formula (1), n is preferably 2 or more, more preferably 2 to 3, and still more preferably 2.0 to 2.5 on average.

In the Formula (1), the vinylbenzyl group may be directly bonded to a carbon atom at the 1-position, the 2-position, or the 3-position of the indene ring, and is directly bonded to a carbon atom at the 1-position or carbon atoms at a combination of the 1-position and the 3-position. At each position, one or two vinylbenzyl groups may be bonded. For example, the vinylbenzyl groups may be bonded to a combination of the 1-position, 1′-position, and 3-position of the indene ring, or to a combination of the 1-position and 1′-position of the indene ring.

In the Formula (1), a methylene group of the vinylbenzyl group may be at any position of o, m, or p, but the position of m or p is preferable. In the Formula (1), two or three vinylbenzyl groups in one molecule may be an o-type, an m-type, or a p-type, or a combination thereof, preferably include a p-type, and may be only a p-type or a combination of an m-type and a p-type. In the resin composition, when two or more kinds of monomers represented by the Formula (1) are included, the positions of the methylene groups of the vinylbenzyl groups between the two or more kinds of monomers may be identical to or different from each other. In the resin composition, when two or more kinds of monomers represented by the Formula (1) are included, in a mixture of two or more kinds of monomers, the vinylbenzyl groups may be one kind or two or more kinds of combinations of an o-type, an m-type, and a p-type, preferably includes a p-type, and may be only a p-type or a combination of an m-type and a p-type. In this case, the mass ratio of an m-type and a p-type in the resin composition or its cured product is preferably 40:60 to 60:40.

Hereinafter, a method for synthesizing the monomer of the polyfunctional vinylbenzyl compound (A) will be described. Note that, the polyfunctional vinylbenzyl compound (A) is a compound identified by its molecular structure, regardless of the synthesis method described below.

Examples of the method for synthesizing the monomer of the polyfunctional vinylbenzyl compound (A) include, for example, a method in which a base compound having a desired structure such as indene or fluorene is allowed to react with styrene having a halogenated methyl group in the presence of a basic compound. Examples of the styrene having a halogenated methyl group include, for example, o-chloromethylstyrene, m-chloromethylstyrene, and p-chloromethylstyrene, and these may be one kind or may be a mixture of two or more kinds. Examples of the basic compound include alkali metal hydroxides and alkali metal alkoxides.

In the above reaction, a phase transfer catalyst may be used. Examples of the phase transfer catalysts include, for example, tetra-n-butylammonium bromide. The reaction can be carried out by solution polymerization. The reaction may be carried out, for example, under heating and stirring. A polymerization inhibitor may be added to a reaction system. The obtained product may be purified by known methods such as concentration, reprecipitation, and washing if necessary.

The obtained monomer may be a single compound or may be a monomer mixture of two or more kinds of compounds. For example, when indene is used as a base compound, a compound, in which the vinylbenzyl group is directly bonded to at least one of the carbon atoms at the 1-position, the 2-position, and the 3-position of the indene ring, is synthesized, but two or more kinds of isomers of polyfunctional vinylbenzyl compounds having different bonding sites may be included in the monomer mixture. In addition, depending on the synthesis conditions, it is possible to obtain a compound, in which the vinylbenzyl groups are each directly bonded to at least two of the carbon atoms at the 1-position, the 2-position, and the 3-position of the indene ring. In this case, two or more kinds of polyfunctional vinylbenzyl compounds having different numbers and sites of vinylbenzyl groups bonded to the indene ring may be included in the monomer mixture.

Hereinafter, a prepolymer of the polyfunctional vinylbenzyl compound (A) will be described.

The polyfunctional vinylbenzyl compound (A) as a prepolymer is preferably a hydrocarbon compound. Among hydrocarbon compounds, a compound having an indene ring, an indane ring, a phenanthrene ring, an acenaphthylene ring, a fluorene ring, or the like, or a combination thereof is preferable, a compound having an indene ring, a fluorene ring, or a combination thereof is more preferable, and a compound having an indene ring is still more preferable. For example, the polyfunctional vinylbenzyl compound (A) may be a prepolymer that has a structural unit having two or more vinylbenzyl groups and one indene ring. That is, the polyfunctional vinylbenzyl compound (A) may include a monomer that has an indene ring and has two or more vinylbenzyl groups bonded to the 1-position, the 2-position, or the 3-position of the indene ring, a polymer of this monomer, or a combination thereof.

A prepolymer can be obtained by polymerizing a monomer. The vinylbenzyl group may be derived from a monomer to be introduced. For example, a monomer having one or two or more vinylbenzyl groups may be used, and a monomer having two or more vinylbenzyl groups is preferably used. The polymerization may be stopped in a state that a certain amount of vinylbenzyl groups derived from the monomer remains without completely completing the polymerization. For example, in order to obtain the prepolymer in a liquid state, the polymerization may be terminated in a state that the viscosity of the polymerization reaction system of the prepolymer reaches a certain degree. In the polymerization of the prepolymer, an oligomer may be used together with or instead of the monomer. For example, in the polymerization of the prepolymer, the monomer of the polyfunctional vinylbenzyl compound (A) described above may be used, or an oligomer of this monomer may be used.

When the polyfunctional vinylbenzyl compound (A) is a prepolymer, the weight average molecular weight (Mw) may be 5,000 to 50,000, or 10,000 to 30,000, in terms of the fluidity of the resin composition.

Next, a method for obtaining the polyfunctional vinylbenzyl compound (A) as a prepolymer by polymerizing the vinylbenzyl compound will be described. The polymerization of the vinylbenzyl compound is preferably carried out by radical polymerization so that polar components are not generated in the reaction product, Radical polymerization can be carried out using a radical polymerization initiator. The polymerization can be carried out by solution polymerization, and a polymerization solvent is not particularly limited. For example, one kind or two or more kinds of organic solvents used in the resin composition described later may be combined and used as the polymerization solvent.

As a radical polymerization initiator, it may be a thermal radical polymerization initiator or may be a photoradical polymerization initiator, but a thermal radical polymerization initiator is preferable. The radical polymerization initiator is not particularly limited, and examples thereof include azo-based polymerization initiators and organic peroxide-based polymerization initiators. Specifically, it may be appropriately selected and used from azo-based polymerization initiators and organic peroxide-based polymerization initiators exemplified as the curing catalyst described later.

The polyfunctional vinylbenzyl compound (A) as a prepolymer may be a homopolymer or may be a copolymer of the vinylbenzyl compound. The copolymer may be a copolymer of two or more kinds of vinylbenzyl compounds or a copolymer of a vinylbenzyl compound and another monomer. In the case of the copolymer, it may be a random copolymer, a block copolymer, or the like.

Among the polyfunctional vinylbenzyl compounds (A), the oligomer may be a polymer having a low degree of polymerization of the aforementioned monomers.

Hereinafter, a styrene copolymer (B) having a weight average molecular weight of 20,000 or less and having a vinyl group will be described. The styrene copolymer (B) is a copolymer different from the polyfunctional vinylbenzyl compound (A).

When the styrene copolymer (B) has a weight average molecular weight of 20,000 or less, the reliability of the product using the cured product of the resin composition can be increased. The reason for this is because stress is alleviated in the coating film of the resin composition, which can suppress the occurrence of fine cracks in the coating film state. The cured product of such a resin composition is excellent in electrochemical migration resistance. A product containing the cured product of such a resin composition has high reliability.

From this perspective, the weight average molecular weight of the styrene copolymer (B) is preferably 20,000 or less, more preferably 15,000 or less, and still more preferably 10,000 or less. The weight average molecular weight of the styrene copolymer (B) may be 1,000 or more, 3,000 or more, or 5,000 or more from the viewpoint of appropriately imparting elasticity to the cured product of the resin composition. For example, the weight average molecular weight of the styrene copolymer (B) may be 1,000 to 20,000, 3,000 to 15,000, or 5,000 to 10,000.

Preferably, the styrene copolymer (B) does not contain an oxygen atom in the molecule. This makes it possible to reduce the amount of polar groups in the obtained cured product, thereby further lowering the relative permittivity and the dissipation factor. Moreover, since the styrene copolymer (B) has a benzene ring derived from styrene in the molecule, it has good compatibility with the polyfunctional vinylbenzyl compound (A) in the resin composition, which can further improve the moldability in the obtained cured product.

When the styrene copolymer (B) has a vinyl group, the heat resistance of the cured product of the resin composition can be improved. The vinyl group in the styrene copolymer (B) may be, for example, one introduced by using the polyvinyl compound as a compound to be copolymerized with styrene, or may be one introduced by obtaining a copolymer including styrene as an essential monomer and then allowing a vinyl compound having a halogenated alkyl group to react.

Examples of the other compounds to be copolymerized with styrene in the styrene copolymer (B) include, for example, α-olefin compounds, cyclic olefin compounds, aromatic vinyl compounds other than styrene, and polyvinyl compounds. The compound to be copolymerized with styrene may be used alone or may be used in combination with two or more kinds.

Examples of the aforementioned α-olefin compounds include, for example, those having 2 to 20 carbon atoms such as ethylene, propylene, 1-butene, 1-hexene, 1-octene, 1-decane, 1-dodecane, 4-methyl-1-pentene, and 3,5,5,-trimethyl-1-hexene.

Examples of the aforementioned cyclic olefin compounds include, for example, norbornene, and cyclopentene.

Examples of the above aromatic vinyl compounds include, for example, alkyl styrene such as methyl styrene and isobutyl styrene, and vinyl naphthalene, and vinyl anthracene.

Examples of the above polyvinyl compounds include, for example, divinylbenzene, divinyl naphthalene, divinyl anthracene, divinyl biphenyl, and alkylene bisstyrenes such as ethylene bisstyrene.

Among these, from the perspective of the balance between the performance as an elastomer and the heat resistance of the cured product of the resin composition, the above α-olefin compound and the above polyvinyl compound are preferably used. That is, the styrene copolymer (B) is preferably a copolymer of styrene, α-olefin compound, and a polyvinyl compound. The α-olefin compound is preferably one having 1 to 8 carbon atoms, and ethylene is particularly preferable. Furthermore, divinylbenzene is preferable as the above polyvinyl compound. Use of divinylbenzene makes it possible to further reduce the amount of polar groups in the obtained cured product, thereby further lowering the relative permittivity and the dissipation factor. In addition, the compatibility with the polyfunctional vinylbenzyl compound (A) in the resin composition becomes even better, which can further improve the moldability of the obtained cured product.

The proportion of styrene relative to the total mass of the copolymer component is preferably 5 to 80 mass %, more preferably 15 to 75 mass %, still more preferably 25 to 70 mass %, and even still more preferably 30 to 60 mass %. Within these ranges, the viscoelasticity of the styrene copolymer (B) also becomes moderate, which can further improve the adhesion of the resin composition to a material to be coated. The proportion of the above α-olefin compound relative to the total mass of the copolymer component is preferably in a range of 10 to 70 mass %, and more preferably in a range of 30 to 55 mass %, from the perspective of the balance between the performance as an elastomer and the heat resistance of the cured product of the resin composition. The proportion of the above polyvinyl compound relative to the total mass of the copolymer component is preferably in a range of 0.05 to 10 mass %, and more preferably in a range of 0.1 to 3 mass %, from the perspective of the balance between the performance as an elastomer and the heat resistance of the cured product of the resin composition.

When a vinyl compound having a halogenated alkyl group as a vinyl group introducing agent for the above styrene copolymer (B) is used, one example of the above compound includes styrene having a halogenated methyl group used in the synthesis of the above polyfunctional vinylbenzyl compound (A).

The above styrene copolymer (B) can be produced by, for example, a method (Method 1) in which styrene and the above polyvinyl compound are polymerized as essential raw materials, or a method (Method 2) in which styrene and another compound are copolymerized, and then a vinyl group introducing agent such as a vinyl compound having the above halogenated alkyl group is allowed to react if necessary. Among these, the Method 1 is preferable because the above styrene copolymer (B) can be more easily produced.

In the Method 1, one example of the method in which styrene and the polyvinyl compound are polymerized as essential raw materials includes, for example, a method in which a single-site coordination polymerization catalyst such as racemic dimethylmethylene bis(4,5-benzo-1-indenyl) zirconium dichloride, dimethylmethylene bis(1-indenyl) zirconium dichloride, or the like is used as a polymerization catalyst. At this time, almoxane such as methylaluminoxane or a boron compound may be used as a co-catalyst. Moreover, in addition to the above almoxane or the boron compound, alkyl aluminum such as triethylaluminum or triisobutylaluminum may also be used in combination. The reaction may be carried out under solvent-free conditions or may be carried out in a solvent such as hexane, cyclohexane, or toluene. The reaction temperature is preferably about 30 to 160° C., and the reaction may be carried out under pressure conditions.

The content of the styrene structural unit of the above styrene copolymer (B) is preferably 5 to 80 mass %, more preferably 15 to 75 mass %, still more preferably 25 to 70 mass %, and even still more preferably 30 to 60 mass %. Within these ranges, the viscoelasticity of the styrene copolymer (B) also becomes moderate, which can further improve the adhesion of the resin composition to a material to be coated. In addition, regarding the structural unit other than styrene, the content of the above α-olefin compound structural unit is preferably in a range of 10 to 70 mass %, and more preferably in a range of 30 to 55 mass %, from the perspective of the balance between the performance as an elastomer and the heat resistance of the cured product of the resin composition. The content of the above polyvinyl compound structural unit is preferably in a range of 0.05 to 10 mass %, and more preferably in a range of 0.1 to 3 mass %.

The resin composition may also include another resin in addition to a prepolymer (A) of the polyfunctional vinylbenzyl compound and the styrene copolymer (B), However, as an elastomer, the styrene copolymer (B) is preferably used in an amount of 50 mass % or more relative to the total amount of the elastomer in order to suppress the occurrence of fine cracks in the cured product of the resin composition. It may be 60 mass %, 80 mass %, or 90 mass % or more, and one kind of the styrene copolymer (B) is more preferably used alone. In addition, as a thermosetting resin, from the perspective of dielectric properties, the polyfunctional vinylbenzyl compound (A) is preferably used in an amount of 50 mass % or more, and may be 60 mass % or 80 mass %, relative to the total amount of the thermosetting resin.

The resin composition may include a resin having a high glass transition temperature (Tg) from the perspective of improving the heat resistance of the cured product of the resin composition. For example, the resin composition may further include a vinyl compound (C) having a glass transition temperature of 150° C. or more. The vinyl compound (C) is a compound different from the polyfunctional vinylbenzyl compound (A) and the styrene copolymer (B). The glass transition temperature (Tg) of the vinyl compound (C) is preferably 150° C. or more, more preferably 170° C. or more, and still more preferably 200° C. or more, from the perspective of the heat resistance of the cured product of the resin composition. The upper limit of the glass transition temperature (Tg) of the resin is not particularly limited, but may be, for example, 300° C. or less.

In the present disclosure, the glass transition temperature (Tg) of the polymer is the measured value according to the following measurement method, unless otherwise specified. The glass transition temperature of the polymer is measured using a differential scanning calorimeter (DSC). For the measurement device, for example, a “DSC Q200” (product name) available from TA Instruments Japan Inc. can be used.

As a specific procedure, the polymer is first dried, and is then cooled to prepare a sample for measurement. 10 mg of the sample for measurement is heated at 10° C./min in a nitrogen (N₂) atmosphere using a differential scanning calorimeter in a temperature range of 25° C. to 400° C., and is then cooled to 25° C. The temperature at which the baseline shifts during re-heating under the same conditions is defined as the glass transition temperature.

The vinyl compound (C) may be a polymer compound having a vinyl group. The vinyl compound (C) is preferably a polymer compound having a plurality of structural units. The vinyl compound (C) may be a homopolymer or may be a copolymer. The vinyl compound (C) may be, for example, a random copolymer, a block copolymer, or the like.

The vinyl compound (C) may contain, for example, one kind or two or more kinds of structural units having a vinyl group. The vinyl compound (C) may contain, for example, one kind or two or more kinds of structural units having a vinyl group and one kind or two or more kinds of structural units having no vinyl group.

The vinyl compound (C) may be, for example, a homopolymer of a monomer having a vinyl group, or may be a copolymer of two or more kinds of monomers that include monomers having a vinyl group. The vinyl compound (C) may be, for example, a copolymer of a monomer containing one kind or two or more kinds of monomers having a vinyl group and one kind or two or more kinds of monomers having no vinyl group.

The vinyl compound (C) may have, for example, a long-chain portion. Examples of the long chain include, for example, alkyl chains.

The weight average molecular weight (Mw) of the vinyl compound (C) is preferably 6,500 or more, more preferably 10,000 or more, still more preferably 25,000 or more, and particularly preferably 30,000 or more, from the viewpoint of adhesion strength with a metal foil. The weight average molecular weight (Mw) of the vinyl compound (C) may be, for example, 50,000 or more. The weight average molecular weight (Mw) of the vinyl compound (C) may be, for example, 100,000 or less, or 50,000 or less. The weight average molecular weight (Mw) of the vinyl compound (C) may, for example, be 30,000 or less. The weight average molecular weight (Mw) of the vinyl compound (C) may be, for example, 6,500 to 100,000, 10,000 to 100,000, 25,000 to 100,000, or 30,000 to 50,000. The weight average molecular weight (Mw) of the vinyl compound (C) may be, for example, 6,500 to 30,000, 25,000 to 50,000, 30,000 to 50,000, or 50,000 to 100,000. In addition, the weight average molecular weight (Mw) of the vinyl compound (C) is preferably 25,000 or more, and more preferably 30,000 or more, from the viewpoint of tackiness.

The number average molecular weight (Mn) of the vinyl compound (C) is preferably 2,000 or more, more preferably 3,000 or more, and still more preferably 4,000 or more, from the viewpoint of adhesion strength with a metal foil. The number average molecular weight of the vinyl compound (C) may be, for example, 10,000 or more. The number average molecular weight of the vinyl compound (C) may be, for example, 20,000 or less, or 10,000 or less. The number average molecular weight of the vinyl compound (C) may be, for example, 4,000 or less. The number average molecular weight of the vinyl compound (C) may be, for example, 2,000 to 20,000, 3,000 to 10,000, or 4,000 to 10,000. The number average molecular weight of the vinyl compound (C) may be, for example, 2,000 to 4,000, 4,000 to 10,000, or 10,000 to 20,000.

The vinyl group equivalent of the vinyl compound (C) is preferably 150 g/eq or more, more preferably 200 g/eq or more, and still more preferably 250 g/eq or more, from the viewpoint of adhesion strength with a metal foil and dielectric properties. The vinyl group equivalent of the vinyl compound (C) may be, for example, 500 g/eq or more. The vinyl group equivalent of the vinyl compound (C) may be, for example, 2,300 g/eq or less, 2,100 g/eq or less, 1,000 g/eq or less, or 500 g/eq or less. The vinyl group equivalent of the vinyl compound (C) may be, for example, 150 g/eq to 2,300 g/eq, 150 g/eq to 2,100 g/eq. 200 to 1,000 g/eq, or 250 g/eq to 500 g/eq. The vinyl group equivalent of the vinyl compound (C) may be, for example, 150 g/eq to 250 g/eq, 250 g/eq to 500 g/eq, or 500 g/eq to 1,000 g/eq.

In the resin composition, the respective contents of the monomer, the oligomer, and the polymer are not particularly limited. Here, in the resin composition, the total amount of the monomer, the oligomer, and the polymer is collectively referred to as a total resin amount PT. The total resin amount PT includes the content of the polyfunctional vinylbenzyl compound (A) and the styrene copolymer (B), optionally includes the content of the vinyl compound (C) having a glass transition temperature of 150° C. or more, and further optionally includes the content of other monomers, oligomers, and polymers. Here, the total resin amount PT optionally also includes the content of the elastomer.

The polyfunctional vinylbenzyl compound (A) is preferably 30 to 80 mass %, more preferably 40 to 75 mass %, and still more preferably 50 to 70 mass %, based on the total resin amount PT. In these ranges, a cured product having better electrochemical migration resistance can be obtained. In addition, the fluidity of the resin composition can be controlled, resulting in good moldability of the metal clad laminate.

The styrene copolymer (B) is preferably 5 to 50 mass %, more preferably 10 to 40 mass %, and still more preferably 20 to 30 mass %, based on the total resin amount PT. In these ranges, the dielectric properties and electrochemical migration resistance of the metal clad laminate are improved.

The vinyl compound (C) having a glass transition temperature of 150° C. or more is preferably 5 to 50 mass %, more preferably 10 to 40 mass %, and still more preferably 20 to 30 mass % based on the total resin amount PT. In these ranges, a cured product having good electrochemical migration resistance can be obtained. In addition, the tackiness of an uncured product or a semi-cured product of a prepreg, a resin film, and the like becomes good.

As one of preferable examples, the resin composition contains 40 to 60 mass % of the polyfunctional vinylbenzyl compound (A), 20 to 30 mass % of the styrene copolymer (B), and 20 to 30 mass % of the vinyl compound (C) having a glass transition temperature of 150° C. or more, relative to the total resin amount PT.

The total content of the polyfunctional vinylbenzyl compound (A) and the styrene copolymer (B) is preferably 20 to 100 mass %, more preferably 40 to 90 mass %, and still more preferably 60 to 80 mass %, based on the total resin amount PT. In these ranges, the fluidity of the resin composition can be controlled, the occurrence of fine cracks in the cured product of the resin composition can be suppressed, and a metal clad laminate having good dielectric properties and electrochemical migration resistance can be produced.

The resin composition may further include a curing catalyst to promote the curing of the polyfunctional vinylbenzyl compound (A).

A radical polymerization initiator can be used as a curing catalyst. As a radical polymerization initiator, it may be a thermal radical polymerization initiator or may be a photoradical polymerization initiator, but a thermal radical polymerization initiator is preferable. The radical polymerization initiator is not particularly limited, and examples thereof include azo-based polymerization initiators and organic peroxide-based polymerization initiators.

Examples of the azo-based polymerization initiators include, for example, 2,2′-azobis(isobutyronitrile), 2,2′-azobis(2-methylpropanenitrile), 2,2′-azobis(2-methylbutyronitrile), 2,2′-azobis(4-methoxy-2,4-dimethylvaleronitrile), dimethyl 2,2′-azobis(2-methylpropionate), 1,1′-azobis(methyl cyclohexylcarboxylate), 2,2′-azobis[N-(2-propenyl)-2-methylpropionamide], 2,2′-azobis(N-butyl-2-methylpropionamide), 4,4′-azobis(3,3,4,4,5,5,6,6,7,7,8,8,8-tridecafluorooctyl 4-cyanopentanoate), and 1,1′-azobis(cyclohexane-1-carbonitrile).

Examples of the organic peroxide-based polymerization initiators include, for example, dicumyl peroxide, dibenzoyl peroxide, 2-butanone peroxide, tert-butyl perbenzoate, di-tert-butyl peroxide, 2,5-dimethyl-2,5-di(t-butylperoxy)hexane, bis(tert-butylperoxyisopropyl)benzene, and tert-butyl hydroperoxide.

In order to prevent the contamination of polar components in the resin composition, it is preferable to reduce the generation of by-products that exhibit polarity in the polymerization system. From this perspective, it is preferable to use a compound having a small amount of oxygen atoms among radical polymerization initiators. The compound described above is preferably an azo-based polymerization initiator. Among them, the azo-based polymerization initiator is preferably a compound that does not contain a heteroatom other than two nitrogen atoms (N) of the azo group. Examples thereof can include, for example, a compound represented by the following Formula (2).

As the azo-based polymerization initiator, the compound represented by the following Formula (2) can be used.

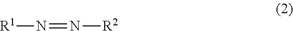

In the Formula (2), R¹ and R² are each independently a hydrogen atom or a monovalent group, and at least one of R¹ and R² is a monovalent group. R¹ and R² may be identical to or different from each other. The monovalent group is preferably a hydrocarbon group, may be a saturated hydrocarbon group or an unsaturated hydrocarbon group, and may be an aliphatic hydrocarbon group or an aromatic hydrocarbon group. The monovalent group is preferably a saturated or unsaturated aliphatic hydrocarbon group, and is preferably an alkyl group.

The alkyl group may be either a chain-type alkyl group or a cyclic alkyl group. The chain-type alkyl group may be a straight-chain alkyl group or may be a branched alkyl group. The cyclic alkyl group may have a substituent bonded to a carbon atom on the ring.

The alkyl group may be, for example, an alkyl group having 1 to 10 carbon atoms, 3 to 8 carbon atoms, or 4 to 8 carbon atoms. Specific examples of the alkyl group include, for example, a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an isohexyl group, a cyclohexyl group, a methylcyclohexyl group, a cyclohexylmethyl group, a heptyl group, an octyl group, an isooctyl group, a 2-ethylhexyl group, a nonyl group, a decyl group, a 1,1′,3,3′-tetramethylbutyl group, and a 2,2′,4,4′-tetramethylbutyl group.

Specific examples of the compound represented by Formula (2) include 2,2′-azobis(2,4,4-trimethylpentane) and 2,2′-azobis(2,4-dimethylvaleronitrile).

The amount of the curing catalyst used may be appropriately adjusted, but may be, for example, 0.01 to 5 parts by mass, 0.1 to 4 parts by mass, or 0.5 to 2 parts by mass, relative to 100 parts by mass of the content of the polyfunctional vinylbenzyl compound (A).

The resin composition may contain inorganic fillers as optional components. Examples of the inorganic fillers include, for example, silica (SiO₂), alumina (Al₂O₃), titanium oxide, barium titanate, strontium titanate, potassium titanate, calcium titanate, aluminum carbonate, magnesium hydroxide, aluminum hydroxide, aluminum silicate, calcium carbonate, calcium silicate, magnesium silicate, silicon nitride, boron nitride, aluminum borate, silicon carbide, mica, beryllia, clay, and talc. Silica is preferable from the perspective of dielectric properties.

The shape and size of the inorganic filler are not particularly limited. The average particle diameter of the inorganic filler may be, for example, 0.01 to 20 μm, or 0.1 to 10 μm. Here, the average particle diameter of the inorganic filler is a particle diameter at a point corresponding to the cumulative value of 50% in the volume-based particle distribution measured by a laser diffraction scattering method.

The inorganic filler may be used alone or may be used in combination of two or more kinds.

The inorganic filler may be 10 to 500 parts by mass, and may be 50 to 400 parts by mass, 100 to 350 parts by mass, or 150 to 300 parts by mass, relative to 100 parts by mass of the solid content of the resin composition. Here, the mass of the solid content of the resin composition is the total mass of components other than the solvent.

When the polyfunctional vinylbenzyl compound (A) is a polymer such as a prepolymer, the resin composition may contain a radical polymerization initiator or its by-products derived from the polymerization of the prepolymer. In this case, using a compound having a small amount of oxygen atoms or a compound that contains no oxygen atom in the radical polymerization initiator, the resin composition may include a small amount of oxygen atoms or to include no oxygen atom in the prepolymer.

The resin composition may be a solvent-free resin composition that contains the polyfunctional vinylbenzyl compound (A) when the polyfunctional vinylbenzyl compound (A) alone or a combination of the polyfunctional vinylbenzyl compound (A) and another resin component is a liquid form. In addition, the resin composition may contain the polyfunctional vinylbenzyl compound (A) and a solvent. The solvent can adjust the viscosity of the resin composition, further improving the coating properties. As the solvent, an organic solvent is preferable.

Examples of the organic solvent include, for example, alcohol-based solvents such as ethanol, propanol, butanol, methyl cellosolve, ethylene glycol monobutyl ether, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur-containing solvents such as dimethyl sulfoxide; and ester-based solvents such as γ-butyrolactone. The organic solvent may be used alone or may be used in combination of two or more kinds.

When the resin composition contains a solvent, components other than the solvent are a solid content, and the amount of the solid content may be 10 to 90 mass %, 30 to 80 mass %, or 50 to 75 mass %, relative to the total mass of the resin composition.

The resin composition may further contain additives other than the above components without impairing the effects of the present invention. Examples of the additives include, for example, flame retardants, curing accelerators, antioxidants, thermal stabilizers, antistatic agents, ultraviolet absorbers, pigments, colorants, and lubricants.

A method for producing the resin composition is not particularly limited. The resin composition according to one embodiment is not limited by the production method, and its characteristics are as described in the present disclosure. As one example of the method for producing the resin composition, the polyfunctional vinylbenzyl compound (A) and the styrene copolymer (B) are mixed with optional components being added thereto if necessary, and therefore the resin composition can be obtained. More specifically, the polyfunctional vinylbenzyl compound (A) and the styrene copolymer (B) are dissolved or dispersed in a solvent, the vinyl compound (C), inorganic fillers, and additives other than the above are added and mixed if necessary, and therefore the resin composition can be obtained. The conditions such as the order of mixing the respective components, the temperature, and the time are not particularly limited and may be appropriately adjusted according to the kind of raw materials, the production scale, the production apparatus, and the like.

### “Cured Product”

According to one embodiment, it is possible to provide a cured product of the resin composition. The details of the resin composition are as described above. Since this cured product has a small amount of polar groups containing oxygen atoms in the polyfunctional vinylbenzyl compound (A) and the styrene copolymer (B), it is possible to reduce the amount of polar groups in the cured product, and to achieve low permittivity and low dissipation factor in the cured product. Moreover, since this resin composition has good compatibility and generates few aggregates, providing a cured product using this resin composition suppresses the occurrence of fine cracks in the cured product, improves electrochemical migration resistance, and enhances the reliability of the product.

The cured product of the resin composition preferably has a relative permittivity (Dk) of 4.0 or less, more preferably 3.5 or less, and still more preferably 3.3 or less, at 25° C. and 10 GHz. More specifically, the cured product of the resin composition may have a relative permittivity (Dk) of 3.30 or less, 3.25 or less, or 3.23 or less, at 25° C. and 10 GHz. A lower relative permittivity (Dk) of the cured product of the resin composition at 25° C. and 10 GHz is preferable, and its lower limit is not particularly limited, and may be, for example, 2.3 or more, or 2.4 or more, considering the balance with other physical properties.

For example, the cured product of the resin composition may have a relative permittivity (Dk) of 2.3 to 4.0, and it may be 2.3 to 3.3, 2.3 to 3.25, or 2.4 to 3.23, at 25° C. and 10 GHz.

The cured product of the resin composition preferably has a dissipation factor (Df) of 0.0020 or less, more preferably 0.0012 or less, and still more preferably 0.0010 or less, at 25° C. and 10 GHz. More specifically, the cured product of the resin composition may have a dissipation factor (Df) of 0.00100 or less, or 0.00099 or less, at 25° C. and 10 GHz. A lower dissipation factor (Df) of the cured product of the resin composition at 25° C. and 10 GHz is preferable, and its lower limit is not particularly limited, and may be, for example, 0.0001 or more, or 0.00050 or more, considering the balance with other physical properties.

For example, the cured product of the resin composition may have a dissipation factor (Df) of 0.0001 to 0.0020, and it may be 0.00050 to 0.00100, or 0.00050 to 0.00099, at 25° C. and 10 GHz.

In the present disclosure, the relative permittivity (Dk) and the dissipation factor (Df) at 25° C. and 10 GHz are measured according to the SPDR method (split-post dielectric resonator) at 25° C. in the 10 GHz band. As the measurement device, “PNA Network Analyzer N5222B” (product name) available from agilent technologies may be used.

As a sample subjected to measurement of the relative permittivity (Dk) and the dissipation factor (Df) of the cured product of the resin composition, a cured product is obtained using the resin composition and is molded into a test piece having a thickness of 130 μm and 5 cm×10 cm for use.

Furthermore, a sample to be measured of the relative permittivity (Dk) and the dissipation factor (Df) of the cured product of the resin composition is one obtained by curing the resin composition to form it in the C-stage state in JIS K 6800 (1985).

### “Prepreg”

According to one embodiment, it is possible to provide a prepreg containing a resin composition or a semi-cured product of the resin composition. The details of the resin composition are as described above.

The prepreg means a state in which the resin composition is impregnated into a fiber substrate. In the prepreg, the resin composition may be in an uncured state or may be partially or fully in a semi-cured state. For example, this prepreg can be used to assemble a molded product such as a laminate, followed by curing through a heat treatment, to obtain a cured product.

The prepreg can be obtained, for example, by coating a resin composition on a fiber substrate, followed by drying. In another method, the prepreg can be obtained by impregnating a fiber substrate with a resin composition and drying the fiber substrate impregnated with the resin composition. Drying is preferably carried out at a temperature equal to or higher than the temperature at which volatile components such as a solvent that may be contained in the resin composition are removed, and may also be carried out at a temperature equal to or higher than the temperature at which the resin composition is semi-cured, depending on the application. Moreover, the drying may be adjusted so that the resin composition is not completely cured. From this perspective, the drying temperature may be 80 to 200° C., and the drying time may be 1 to 30 minutes depending on the drying temperature, the drying apparatus, its scale, and the like.

In the present disclosure, a semi-cured product of the resin composition means a state in which some of the vinylbenzyl groups and vinyl groups contained in the resin composition contribute to the curing reaction, and the remaining vinylbenzyl groups and vinyl groups remain. The semi-cured product is in a state in which the curing reaction can continue by application of an additional heating treatment or the like. In the present disclosure, as one indicator of the semi-cured product, the B-stage state in JIS K 6800 (1985) can be exemplified.

The fiber substrate may be any of a woven fabric, a knitted fabric, or a non-woven fabric. The fiber substrate may be provided in the form of chopped strand mat, roving, and the like. The material of the fibers may be either inorganic fibers or organic fibers. Examples of the inorganic fibers include glass fibers and carbon fibers. Examples of the glass fibers include E-glass, NE-glass, D-glass, S-glass, and Q-glass. Examples of the organic fibers include polyimide, polyester, and tetrafluoroethylene. The fiber substrate may be these fibers alone or mixed fibers of two or more kinds thereof. From the perspective of dielectric properties and heat resistance, the fiber substrate is preferably inorganic fibers, and more preferably glass fibers.

The fiber substrate may be appropriately selected according to the application of the prepreg, but a sheet-like fiber substrate is preferable. As a sheet-like fiber substrate, for example, various sheet-like fiber substrates used in known laminates for electrical insulation materials may be used. The thickness of the sheet-like fiber substrate is not particularly limited, but is preferably, for example, 0.02 to 0.5 mm. Here, thicknesses at five points evenly spaced across the entire surface of the sheet-like fiber substrate are measured, and the thickness is determined from an arithmetic average value of the thicknesses at the five points.

In the prepreg, the total mass of the resin composition may be 20 to 90 mass %, and may also be 30 to 80 mass %, relative to the total mass of the prepreg. Within these ranges, the impregnation coating of the resin into the fiber substrate in the prepreg can be more easily carried out. Moreover, a step of assembling the prepreg into a molded product, followed by curing can be more easily carried out.

### “Resin Film”

According to one embodiment, it is possible to provide a resin film containing a resin composition or a semi-cured product of the resin composition. The details of the resin composition are as described above.

The resin film means a state in which the resin composition is molded into a film form. In the resin film, the resin composition may be in an uncured state or may be partially or fully in a semi-cured state. This resin film can be cured a through heat treatment or the like, to obtain a cured product.

The resin film can be obtained, for example, by coating a resin composition on a material to be coated, followed by drying. Drying may be carried out, for example, in the same manner as the production method of the prepreg described above. After the resin film is dried on the material to be coated, a product may be provided as a combination of the resin film and the material to be coated. In this method, the resin film can be provided in order to form an insulating layer or the like on the material to be coated in electronic devices and the like. In another method, after the resin film is dried on the material to be coated, the resin film may be peeled off from the material to be coated and the resin film may be provided as a product.

The material to be coated may be either an inorganic substrate or an organic substrate, and examples thereof include glass substrates, metal substrates such as metal foils and metal plates, plastic substrates such as plastic plates and plastic films, and paper substrates, and may also be the fiber substrate described in the above prepreg. In order to provide the resin film by peeling it off from the material to be coated, a material to be coated having a release layer formed on the surface may be used.

### “Metal Clad Laminate”

According to one embodiment, it is possible to provide a metal clad laminate including a cured product of a resin composition and a metal foil. The cured product of the resin composition may be a cured product of the resin composition or a cured product of the prepreg. The details of the resin composition and the prepreg are as described above.

The metal clad laminate preferably includes a resin cured product layer containing the resin cured product and a metal foil formed on at least one surface of the resin cured product layer. The resin cured product layer contains the cured product of the resin composition, but may be the cured product of the prepreg described above. For more useful applications, a metal foil is formed on at least one surface of the cured product of the prepreg, and a metal foil is more preferably formed on both surfaces of the cured product of the prepreg. The metal clad laminate may be produced by forming a metal foil on at least one surface of one sheet-like prepreg, or may be produced by laminating two or more sheet-like prepregs and forming a metal foil on at least one surface of the outermost surface of the laminate. For more useful applications, the metal clad laminate is produced by laminating two or more sheet-like prepregs and forming a metal foil on both surfaces of this laminate.

Hereinafter, as a specific example of a method for producing the metal clad laminate, a method in which a metal foil is formed on a laminate of two or more sheet-like prepregs will be described.

First, two or more sheet-like prepregs are combined to obtain a laminate. In the laminate, the two or more sheet-like prepregs may be identical to each other, or some or all may be different. In the laminate, at least one sheet-like prepreg of the two or more sheet-like prepregs may be obtained using the resin composition according to one embodiment. Next, a metal foil is formed on at least one surface of this laminate. For example, a molded product of the metal foil can be prepared, and the metal foil can be bonded to the laminate to form a metal foil on the laminate.

Next, the laminate in which the metal foil is formed can be heated and pressurized to produce a metal clad laminate. This allows the curing reaction of the sheet-like prepreg to proceed and to obtain a cured product of the prepreg. In addition, sheet-like prepregs adjacent to each other can be fixed. The heating and pressurizing conditions are not particularly limited, but for example, the temperature can be set to 100 to 300° C., the time can be set to 10 to 300 minutes, and the pressure can be set to 1.5 to 5 MPa. In addition, after pressurization, reheating may be carried out to further advance the curing of the prepreg. In this case, the reheating temperature may be 100 to 300° C. As a pressurization method, for example, an autoclave molding machine, a multi-stage press machine, a multi-stage vacuum press machine, a continuous molding machine, and the like can be used.

The dielectric properties of the resin cured product in a state in which the metal foil is removed from the assembled metal clad laminate (simply, also referred to as the dielectric properties of the metal clad laminate) are preferably as follows.

The metal clad laminate has a relative permittivity (Dk) of preferably 4.0 or less, more preferably 3.5 or less, and still more preferably 3.3 or less, at 25° C. and 10 GHz. More specifically, the metal clad laminate may have a relative permittivity (Dk) of 3.30 or less, 3.25 or less, or 3.23 or less, at 25° C. and 10 GHz. A lower relative permittivity (Dk) of the metal clad laminate at 25° C. and 10 GHz is preferable, and its lower limit is not particularly limited, and may be, for example, 2.3 or more, or 2.4 or more, considering the balance with other physical properties.

For example, the metal clad laminate may have a relative permittivity (Dk) of 2.3 to 4.0, and it is preferably 2.3 to 3.3, 2.3 to 3.25, or 2.4 to 3.23, at 25° C. and 10 GHz.

The dissipation factor (Df) of the metal clad laminate is preferably 0.0020 or less, more preferably 0.0012 or less, and still more preferably 0.0010 or less, at 25° C. and 10 GHz. More specifically, the dissipation factor (Df) of the metal clad laminate may be 0.00100 or less or 0.00099 or less at 25° C. and 10 GHz. A lower dissipation factor (Df) of the metal clad laminate at 25° C. and 10 GHz is preferable, and its lower limit is not particularly limited, and may be, for example, 0.0001 or more or 0.00050 or more, considering the balance with other physical properties.

For example, the dissipation factor (Df) of the metal clad laminate may be 0.0001 to 0.0020, and is preferably 0.00050 to 0.00100 or 0.00050 to 0.00099, at 25° C. and 10 GHz.

The measurement of the relative permittivity (Dk) and the dissipation factor (Df) of the metal clad laminate may be carried out according to the measurement of the relative permittivity (Dk) and the dissipation factor (Df) of the cured product of the resin composition described above.

The sample subjected to measurement of the relative permittivity (Dk) and the dissipation factor (Df) of the metal clad laminate is used by immersing the metal clad laminate in an etching solution to remove a copper foil from the resin cured product, and cutting an evaluation substrate of 5 cm×10 cm having a thickness of 130 μm from the test piece from which the copper foil has been removed. In the case of the copper clad laminate, a 10 mass % ammonium persulfate solution is used as the etching solution.

### “Printed Wiring Board”

According to one embodiment, it is possible to provide a printed wiring board including a cured product of a resin composition. The details of the resin composition are as described above.

In the printed wiring board, the cured product of the resin composition can be produced using the resin composition, the prepreg, the resin film, the metal clad laminate, or a combination thereof. For example, an insulating layer can be formed by coating and curing the resin composition on a surface or the like of the substrate of the printed wiring board, and then a printed wiring board can be provided. In other examples, a printed wiring board can be provided using a metal clad laminate as the substrate of the printed wiring board. It may also be a printed wiring board that combines these examples. The details of the prepreg, the resin film, and the metal clad laminate are as described above.

The printed wiring board may be either a single-layer printed wiring board or a multi-layer printed wiring board. In the case of the multi-layer printed wiring board, it may be multi-layered using the prepreg, the resin film, the metal clad laminate, or a combination thereof.

### “Semiconductor Package”

According to one embodiment, it is possible to provide a semiconductor package that includes a printed wiring board including a cured product of a resin, and a semiconductor element. The details of the resin composition are as described above. The details of the cured product of the resin composition and the printed wiring board are as described above. The semiconductor package can be produced, for example, by mounting a semiconductor element, a memory, and the like, in a printed wiring board using a known method. A resin cured product may be used as an insulating material, a sealing material, and the like for the semiconductor package.

Examples of the embodiments of the present disclosure are listed below. The present invention is not limited to the following embodiments.
<1> A resin composition comprising a polyfunctional vinylbenzyl compound (A) having two or more vinylbenzyl groups, and a styrene copolymer (B) having a weight average molecular weight of 20,000 or less and having a vinyl group.
<2> The resin composition according to <1>, wherein the polyfunctional vinylbenzyl compound (A) includes a compound having an indene ring.
<3> The resin composition according to <1> or <2>, wherein the polyfunctional vinylbenzyl compound (A) includes a monomer that has an indene ring and has two or more vinylbenzyl groups bonded to a 1-position, a 2-position, or a 3-position of the indene ring, a polymer of this monomer, or a combination thereof.
<4> The resin composition according to any one of <1> to <3>, further comprising a vinyl compound (C) having a glass transition temperature of 150° C. or more, wherein the vinyl compound (C) is a compound different from the polyfunctional vinylbenzyl compound (A) and the styrene copolymer (B).
<5> The resin composition according to <4>, wherein the vinyl compound (C) has a weight average molecular weight of 25,000 or more.
<6> The resin composition according to any one of <1> to <5>, wherein a cured product of the resin composition exhibits a relative permittivity of 2.3 to 3.3 at a measurement temperature of 25° C. and a frequency of 10 GHz.
<7> The resin composition according to any one of <1> to <6>, wherein a cured product of the resin composition exhibits a dissipation factor of 0.00050 to 0.00100 at a measurement temperature of 25° C. and a frequency of 10 GHz.
<8> A prepreg comprising the resin composition according to any one of <1> to <7> or a semi-cured product of the resin composition.
<9> A metal clad laminate comprising a cured product of the resin composition according to any one of <1> to <7> and a metal foil.
<10> A resin film comprising the resin composition according to any one of <1> to <7> or a semi-cured product of the resin composition.
<11> A printed wiring board comprising a cured product of the resin composition according to any one of <1> to <7>.
<12> A semiconductor package comprising the printed wiring board according to <11> and a semiconductor element.

### Examples

Hereinafter, the present invention will be further specifically described by way of Examples, but the present invention is not limited to the following Examples.

### “Production of Vinylbenzyl Compound”

Into a 500 mL-volume reaction vessel equipped with a stirring device, a thermometer, a reflux tube, and a nitrogen blowdown inlet, 35.6 parts by mass of indene, 101.2 parts by mass of chloromethylstyrene as described below, 7.1 parts by mass of tetra-n-butylammonium bromide (available from KANTO CHEMICAL CO., INC.) as a phase transfer catalyst, 0.1 parts by mass of phenothiazine as a polymerization inhibitor, and 77.6 parts by mass of toluene as a solvent were charged, and heated and stirred at 40° C. while nitrogen was blown at a flow rate of 50 mL/min.

Chloromethylstyrene “CMS-P”: AGC Seimi Chemical Co., Ltd., a mixture of an m-type and a p-type, a content of the m-type is 50 mass % and a content of the p-type is 50 mass %.

Next, 46.5 parts by mass of an aqueous solution of the following basic compound was added dropwise over 20 minutes and was further stirred at 60° C. for 9 hours. During the reaction, nitrogen blowing was continued. After cooling to room temperature (25° C.) and neutralizing with a 10% hydrochloric acid aqueous solution, washing with pure water was carried out twice. After toluene was removed under reduced pressure, the obtained viscous liquid was washed with methanol, followed by vacuum drying, to obtain a vinylbenzyl compound.

Aqueous solution of the basic compound: An aqueous solution of sodium hydroxide having a concentration of 48% by mass, KANTO CHEMICAL CO., INC.

It was confirmed by 1H-NMR analysis that the obtained vinylbenzyl compound was a structure having a vinylbenzyl group directly bonded to a carbon atom at the 1-position, the 3-position, or a combination thereof of the indene represented by the following Formula (3). By GPC analysis, the vinylbenzyl compound was a mixture of a compound into which two vinylbenzyl groups were introduced and a compound into which three vinylbenzyl groups were introduced. When three vinylbenzyl groups were introduced into the vinylbenzyl compound, it was confirmed that it has two vinylbenzyl groups directly bonded to the carbon atom at 1-position of the indene ring and has one vinylbenzyl group directly bonded to the carbon atom at the 3-position. The weight average molecular weight (Mw) of the vinylbenzyl compound was 500. The weight average molecular weight was measured by the following method.

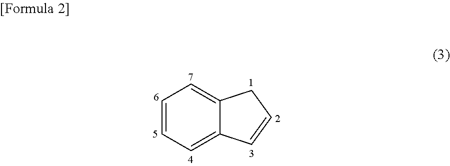

### “Measurement Method of Weight Average Molecular Weight (Mw)”

The weight average molecular weight was converted from a calibration curve using standard polystyrene by gel permeation chromatography (GPC). The calibration curve was approximated by a cubic equation using standard polystyrene: TSKstandard POLYSTYRENE (Type; A-2500, A-5000, F-20, F-80) (available from Tosoh Corporation, product name). The measurement conditions of GPC are shown below.
Device: High-speed GPC device HLC-8320GPC (Tosoh Corporation, product name)
Detector: Ultraviolet absorbance detector UV-8320 (Tosoh Corporation, product name)
Column: Guard column; TSKgel guardcolumn Super (HZ)-M+, Column; TSKgel SuperMultipore HZ-M (2 columns), Reference column; TSKgel SuperH-RC (2 columns) (all from Tosoh Corporation, product names)
Column size: 4.6×20 mm (guard column), 4.6×150 mm (column), 6.0×150 mm (reference column)
Eluent: Tetrahydrofuran
Sample concentration: 10 mg/1 mL.
Injection amount: 20 μL or 2 μL
Flow rate: 0.35 mL/min
Measurement temperature: 40° C.

### “Preparation of Resin Composition”

Each component shown in Table 1 was formulated with toluene according to the content shown in the table, and was stirred and mixed at 25° C. to produce a resin composition having a solid content concentration of about 75 mass %. In the table, the unit of the formulation amount of each component is parts by mass. In the case of a solution, it means parts by mass in terms of the solid content.

The components used are as follows.
Polyfunctional vinylbenzyl compound (A): One produced above was used.
Styrene copolymer (B): A styrene copolymer having a vinyl group (styrene ratio 51 mass %, ethylene ratio 48 mass %, divinylbenzene ratio 1 mass %, weight average molecular weight (Mw): 9,000).
Styrene copolymer for reference: Styrene-ethylene-butadiene-styrene copolymer (styrene ratio: 20 mass %, weight average molecular weight (Mw): 78,000, one having no vinyl group in the molecule of the copolymer).
Bismaleimide compound: Bismaleimide compound (Mn=1300).
Vinyl compound (C): Vinyl compound (a compound with Tg≥150° C., vinyl group equivalent: 265 g/eq, weight average molecular weight (Mw): 36,000, number average molecular weight (Mn): 3,300).
Silica filler: Average particle diameter 2.4 μm.

The glass transition temperature of the vinyl compound (C) is the numerical value measured using a differential scanning calorimeter (DSC). For the measurement device, a “DSC Q200” (product name) available from TA Instruments Japan Inc. is used.

As a specific procedure, the vinyl compound (C) is first dried, and is then cooled to prepare a sample for measurement. 10 mg of the sample for measurement is heated at 10° C./min in a nitrogen (N₂) atmosphere using a differential scanning calorimeter in a temperature range of 25° C. to 400° C., and is then cooled to 25° C. The temperature at which the baseline shifts during re-heating under the same conditions is defined as the glass transition temperature.

### “Preparation of Prepreg”

The obtained resin composition was impregnated and coated onto a NE glass cloth having a thickness of 0.03 mm (NITTO BOSEKI CO., LTD.), and was heated and dried at 130° C. for 4 minutes, to obtain a prepreg in which a content of the solid content derived from the resin composition was 80 mass %.

### “Preparation of Copper Clad Laminate”

On both sides of the obtained prepreg, a low-profile copper foil having a thickness of 18 μm (SI-VSP18, available from MITSUI KINZOKU COMPANY, LIMITED, “VSP” is a registered trademark) was stacked so that the matte surface was united together with the prepreg, and was heated and pressurized under vacuum conditions of 2 MPa at 230° C. for 80 minutes, to produce a copper clad laminate (CCL). The size of the copper clad laminate was set to a thickness of 130 μm and a size of 5 cm×10 cm.

### “Evaluation Method and Measurement Method”

Evaluation and measurement were carried out as described below, and the results are shown in the table.

### (Dielectric Properties of Copper Clad Laminate)

The produced copper clad laminate was immersed in a 10 mass % solution of ammonium persulfate (available from MITSUBISHI GAS CHEMICAL COMPANY, INC.) as a copper etching solution, to remove the copper foil on both sides of the prepreg, and an evaluation substrate of 5 cm×10 cm was cut from the substrate from which the copper foil was removed. The thickness of the evaluation substrate is 130 μm.

Using this evaluation substrate, the relative permittivity (Dk) and the dissipation factor (Df) were measured at 25° C. in the 10 GHz band according to the SPDR method (split-post dielectric resonator). As the measurement device, “PNA Network Analyzer N5222B” (product name) available from agilent technologies was used.

### (Electrochemical Migration Resistance (Conductive Anodic Filaments (CAF)) Evaluation)

Using the same procedure as the production method of the above copper clad laminate, a double-sided copper clad laminate having a thickness of 0.8 mm and a size of 230 mm×230 mm was produced. A pattern shown in FIG. 1 was formed on this copper clad laminate. The drilling conditions for forming the patterns were a drill diameter of 0.4 @mm, a rotation speed of 80,000 rpm, and a feed speed of 1.2 m/min, a spacing between drilled holes was 0.3 mm, and the number of the holes was 320. A resist film was applied for the purpose of preventing damage to the patterns during the formation of the patterns. After the holes were drilled, about 20 μm of copper plating was applied inside the holes. Thereafter, a heat treatment step was repeated six times until the surface temperature of the obtained sample was maintained at 260° C. or more for 10 seconds and then cooled to room temperature (about 25° C.), to thereby obtain a sample for CAF evaluation. After the obtained sample was placed in a constant temperature chamber at 85° C./85% RH for 96 hours, a DC voltage of 100 V was applied within the chamber. Regarding the evaluation criteria, a sample that always showed 1.0 E+06Ω or more during 500 hours from the start of measurement was evaluated as OK and a sample that showed a resistance value below it was evaluated as NG. This test was evaluated with N=5 for one test number. The electrochemical migration resistance was evaluated based on the following criteria.
A: In N=5, the number of OK is 4 or 5.
B: In N=5, the number of OK is 1 to 3.
C: In N=5, the number of OK is 0.

### (Dielectric Properties of Cured Product of Resin Composition)

The resin composition obtained above was coated on a polyethylene terephthalate (PET) film (available from TEIJIN LIMITED, product name: G2000) having a thickness of 38 μm and was heated and dried at 130° C. for 10 minutes to produce a resin film in the B-stage state. After the resin film was peeled from the PET film, it was crushed to obtain resin powder.

Next, a Teflon (registered trademark) sheet that was die-cut to have a size of 0.3 mm thick×50 mm long×40 mm wide was positioned on the copper foil, and the resin powder was charged into the die-cut portion. Furthermore, copper foil was disposed thereon to obtain a laminate. The copper foil used was a low-profile copper foil having a thickness of 18 μm (available from MITSUI KINZOKU COMPANY, LIMITED, product name: SI-VSP), and was disposed so that the S surface (glossy surface) was in contact with the resin powder charged. Thereafter, the laminate was subjected to vacuum heating and pressure molding under conditions of the temperature of 230° C., the pressure of 2 MPa, and the time of 90 minutes, to cure the resin composition. After that, the copper foils on both sides were removed to obtain a resin plate.

Using this test piece, the relative permittivity (Dk) and the dissipation factor (Df) were measured at 25° C. in the 10 GHz band according to the SPDR method (split-post dielectric resonator). As the measurement device, “PNA Network Analyzer N5227A” (product name) available from agilent technologies was used.

TABLE 1

| Item | | Unit | Example 1 | Example 2 | Example 3 | Example 4 |
|---|---|---|---|---|---|---|
| Polyfunctional vinylbenzyl compound (A) | | mass % | 19 | 15 | 15 | 19 |
| Styrene copolymer (B) | | | — | — | — | 6 |
| Styrene copolymer for reference | | | — | — | 9 | — |
| Bismaleimide compound | | | 6 | — | 6 | — |
| Vinyl compound (C) | | | 6 | 15 | — | 6 |
| Silica filler | | | 69 | 69 | 69 | 69 |
| Dielectric properties of copper | Relative permittivity | — | 3.31 | 3.33 | 3.31 | 3.32 |
| | (Dk) | | | | | |
| clad laminate | Dissipation factor (Df) | — | 0.00130 | 0.00118 | 0.00113 | 0.00112 |
| Dielectric properties of cured | Relative permittivity | — | 3.12 | 3.15 | 3.12 | 3.14 |
| | (Dk) | | | | | |
| product of resin composition | Dissipation factor (Df) | — | 0.00100 | 0.00085 | 0.00079 | 0.00078 |
| Electrochemical migration | CAF evaluation | — | B | C | C | A |
| resistance | | | | | | |

As shown in the table, when the resin composition of Example 4, which contained the polyfunctional vinylbenzyl compound (A) and the styrene copolymer (B), was used, the copper clad laminate exhibited low permittivity and low dissipation factor, and exhibited excellent electrochemical migration resistance. The excellent electrochemical migration resistance is found to have high reliability as a product. In addition, the resin composition of Example 4 also exhibited excellent dielectric properties of the cured product of the resin composition. In Examples 1 to 3, when the resin compositions containing no styrene copolymer (B) were used, the electrochemical migration resistances of the copper clad laminates were decreased.

### INDUSTRIAL APPLICABILITY

The resin compositions according to some embodiments of the present disclosure and the products formed using the same can be applied as substrate materials and the like for metal clad laminates such as copper clad laminates, and printed wiring boards, in, for example, mobile communication devices represented by smartphones, network infrastructure devices such as its base station devices, servers, and routers, and electronic devices such as large computers, expected to have high speed of signals and large capacity.

The present disclosure is related to the subject matter described in Japanese Patent Application No. 2023-181836, filed Oct. 23, 2023, all the disclosed contents of which are incorporated herein by reference. It should be noted that various modifications or alternations may be made to the above embodiments without departing from the novel and advantageous features of the present disclosure other than those already mentioned. Therefore, all such modifications or alternations are intended to be included within the scope of the attached claims.

1. A resin composition comprising a polyfunctional vinylbenzyl compound (A) having two or more vinylbenzyl groups, and a styrene copolymer (B) having a weight average molecular weight of 20,000 or less and having a vinyl group.

2. The resin composition according to claim 1, wherein the polyfunctional vinylbenzyl compound (A) includes a compound having an indene ring.

3. The resin composition according to claim 1, wherein the polyfunctional vinylbenzyl compound (A) includes a monomer that has an indene ring and has two or more vinylbenzyl groups bonded to a 1-position, a 2-position, or a 3-position of the indene ring, a polymer of this monomer, or a combination thereof.

4. The resin composition according to claim 1, further comprising a vinyl compound (C) having a glass transition temperature of 150° C. or more, wherein the vinyl compound (C) is a compound different from the polyfunctional vinylbenzyl compound (A) and the styrene copolymer (B).

5. The resin composition according to claim 4, wherein the vinyl compound (C) has a weight average molecular weight of 25,000 or more.

6. The resin composition according to claim 1, wherein a cured product of the resin composition exhibits a relative permittivity of 2.3 to 3.3 at a measurement temperature of 25° C. and a frequency of 10 GHz.

7. The resin composition according to claim 1, wherein a cured product of the resin composition exhibits a dissipation factor of 0.00050 to 0.00100 at a measurement temperature of 25° C. and a frequency of 10 GHz.

8. A prepreg comprising the resin composition according to claim 1 or a semi-cured product of the resin composition.

9. A metal clad laminate comprising a cured product of the resin composition according to claim 1 and a metal foil.

10. A resin film comprising the resin composition according to claim 1 or a semi-cured product of the resin composition.

11. A printed wiring board comprising a cured product of the resin composition according to claim 1.

12. A semiconductor package comprising the printed wiring board according to claim 11 and a semiconductor element.

13. The resin composition according to claim 1, wherein
the polyfunctional vinylbenzyl compound (A) includes a monomer that has an indene ring and has two or more vinylbenzyl groups bonded to a 1-position, a 2-position, or a 3-position of the indene ring, a polymer of this monomer, or a combination thereof,
the resin composition further comprising a vinyl compound (C) having a glass transition temperature of 150° C. or more,
the vinyl compound (C) has a weight average molecular weight of 25,000 or more, and
the vinyl compound (C) is a compound different from the polyfunctional vinylbenzyl compound (A) and the styrene copolymer (B).

14. The resin composition according to claim 13, wherein a cured product of the resin composition exhibits a relative permittivity of 2.3 to 3.3 at a measurement temperature of 25° C. and a frequency of 10 GHz.

15. The resin composition according to claim 13, wherein a cured product of the resin composition exhibits a dissipation factor of 0.00050 to 0.00100 at a measurement temperature of 25° C. and a frequency of 10 GHz.
